(19) United States
(12) Patent Application Publication
(10) Pub. No.: US 2008/0093749 A1
(43) Pub. Date: Apr. 24, 2008

(54) Partial Solder Mask Defined Pad Design

(75) Inventors: Mark Allen Gerber, Lucas, TX (US); Wyatt Allen Huddleston, Allen, TX (US); Shawn Martin O'Connor, McKinney, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/551,508

(22) Filed: Oct. 20, 2006

(51) Int. Cl. H01L 23/52

(52) U.S. Cl. 257/784

(57) ABSTRACT

A solder ball pad that includes a substrate and a bonding pad attached to the substrate. The bonding pad has a bonding pad surface and a bonding pad edge. The solder ball pad also includes a solder mask attached to the substrate in which the solder mask at least partially surrounds, but does not substantially cover, the bonding pad. The solder ball pad also has an anchor pad coupled to the bonding pad and extending between the substrate and the solder mask.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO A MICROFICHE APPENDIX

Not applicable.

### FIELD

The present disclosure is directed to Ball Grid Array (BGA) integrated circuit package, and more particularly, but not by way of limitation, to solder ball pad designs and solder ball connections in the BGA package.

### BACKGROUND

An integrated circuit chip may require a carrier or package in order to be incorporated into a larger electronic system. The package may consist of a substrate along with a conductive pattern for connection to the chip. The substrate has a top surface and a bottom surface with either one or both surfaces having the conductive pattern. The conductive pattern usually has bonding pads for electrical connection to the integrated circuit chip and for alternate connections to larger systems, for example, mother boards or electronic carriers. The substrate may also be coated with a solder mask that may partially cover the conductive pattern. The solder mask is intended to provide a pattern of openings that allow electrical and mechanical connection to the bonding pads, but prevent solder from bonding to other areas or bridging between pads. A package that has an array of openings in the solder mask on one side to allow for an array of solder ball bonds is commonly called a Ball Grid Array (BGA) package.

In a BGA package, the connection between the solder ball and the package is limited to the contact area between the solder ball and the bonding pad. The solder mask, which surrounds the bonding pad, is typically made of a material that has a weak interfacial connection strength with a metallic solder ball. Thus, any bond between a solder ball and the solder mask does not usually result in a useful mechanical bond even if the solder ball contacts the solder mask. As a result, the solder ball connection to the bonding pad may be limited in area and may be mechanically weak. This weak connection may break and cause a package or device failure due to sudden impacts, temperature cycling of the connection or substrate, or mechanical bending of the substrate. Therefore, a need exists for improved solder ball connection techniques that create stronger solder ball connections in BGA packages.

### SUMMARY

The present disclosure provides a solder ball pad that includes a substrate and a bonding pad attached to the substrate. The bonding pad has a bonding pad surface and a bonding pad edge. The solder ball pad also includes a solder mask attached to the substrate in which the solder mask at least partially surrounds, but does not substantially cover, the bonding pad. The solder ball pad also has an anchor pad coupled to the bonding pad and extending between the substrate and the solder mask.

In an embodiment, a ball grid array (BGA) package is provided. The BGA package includes a substrate and a conductive pattern disposed on the substrate. The BGA package also includes a solder ball pad, which comprises a bonding pad and an anchor pad, disposed on the substrate and electrically coupled to the conductive pattern. The BGA package also comprises a solder mask coated on the substrate that substantially covers the conductive pattern and the anchor pads, but does not substantially cover the bonding pad.

In an embodiment, a method is disclosure for manufacturing a BGA package. The method includes disposing a conductive pattern on a substrate, disposing a solder ball pad, which comprises a bonding pad and an anchor pad, on the substrate, and electrically coupling the solder ball pad to the conductive pattern. The method also includes coating the substrate with a solder mask so that the solder mask covers at least a part of the conductive pattern and the anchor pads. The method further comprises connecting a solder ball to the bonding pad.

### BRIEF DESCRIPTION OF THE DRAWINGS

For a more complete understanding of the present disclosure and the advantages thereof, reference is now made to the following brief description, taken in connection with the accompanying drawings and detailed description, wherein like reference numerals represent like parts.

FIG. 1 is a cross-sectional view of an integrated circuit Ball Grid Array (BGA) package.

FIG. 2 is a top view of a partial solder mask defined solder ball pad design.

FIG. 3A is a cross-sectional view of a solder ball pad taken along line A-A as defined in FIG. 2.

FIG. 3B is a cross-sectional view of a solder ball pad taken along line B-B as defined in FIG. 2.

FIG. 4A is a cross-sectional of a solder ball attached to a bond pad.

FIG. 4B is a cross-sectional of a solder ball attached to a bond pad.

FIG. 5 shows one embodiment of a placement of solder ball pads arranged in an array with possible via locations.

FIG. 6 shows another embodiment of a placement of solder ball pads arranged in an array with possible via locations.

FIG. 7 shows another embodiment of a placement of solder ball pads arranged in an array with possible via locations.

FIG. 8 shows another embodiment of a placement of solder ball pads arranged in an array with possible via locations.

FIG. 9 shows another embodiment of a placement of solder ball pads arranged in an array with possible via locations.

FIG. 10 is a flow diagram of a method for manufacturing a BGA package.

### DETAILED DESCRIPTION

It should be understood at the outset that although an exemplary implementation of one embodiment of the present disclosure is illustrated below, the present system may be implemented using any number of techniques, whether currently known or in existence. The present disclosure should in no way be limited to the exemplary implementations, drawings, and techniques illustrated below, including the exemplary design and implementation illustrated and described herein, but may be modified within the scope of the appended claims along with their full scope of equivalents.

The present disclosure contemplates a solder ball pad design having a bonding pad available to bond to a solder ball and an anchor pad extending outward from the bonding pad between a substrate and a surrounding solder mask. The disclosed design allows for a solder ball to bond to a bonding pad edge and a surface, which may allow the mechanical bonding strength to be improved relative to a design with only a portion of the bonding pad surface available. The disclosed design also allows for an anchor pad that may increase the mechanical connection strength between the bonding pad and the substrate relative to a design without an anchor pad. The present disclosure further includes a Ball Grid Array (BGA) package comprising a plurality of the disclosed solder ball pads that may result in an improved package performance as measured by existing package performance test procedures.

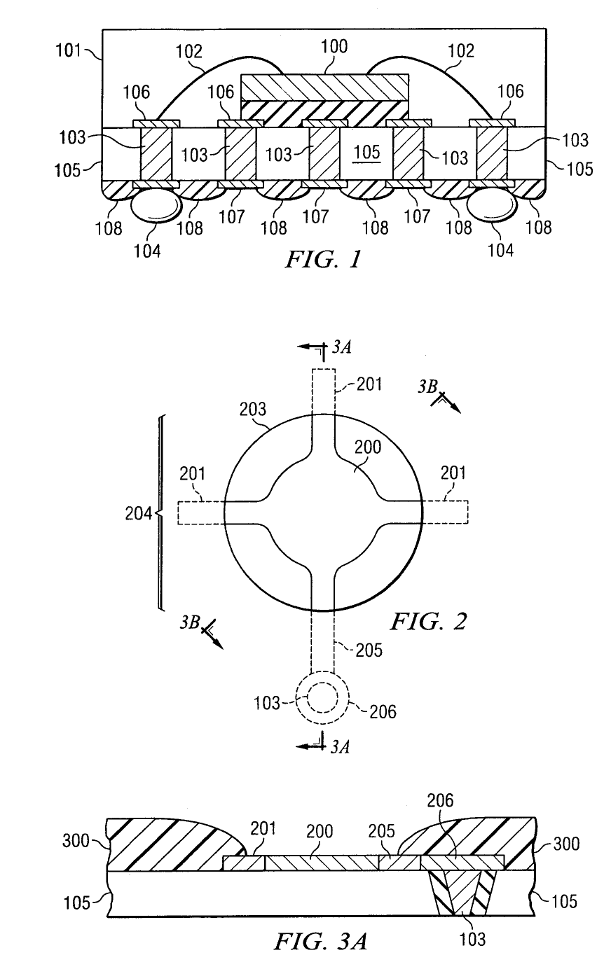

In an embodiment shown in FIG. 1, an integrated circuit (IC) or semiconductor die (“die”) 100 is packaged using a package substrate 105 that has two sides. The first side holds the die 100 and may contain bonding pads 106 for electrical connection to the die, for example, using wire bonds. Wire bonding uses bond wires 102 to electrically connect the bonding pad 106 and the die 100. The first side may also be filled or covered with a mold compound 101 to secure the die 100 to the substrate 105 and protect the wires 102 used for wire bonding. The second side may have an array of connection points for connection to a larger electronic system. One possible method of connection is through the use of a solder ball 104 and a solder ball pad 107. In this embodiment, a solder ball 104 is attached to a solder ball pad 107 leaving a solder ball surface extending out from the substrate 105 beyond a solder mask 108. The solder balls 104 may be electrically connected to the die 100 or bonding pads 106 through the use of vias 103 that provide electrical connection between the two sides of the substrate 105. In an embodiment, a system that uses an array of solder balls 104 to connect to a larger system is typically referred to as a BGA.

The substrate 105 is used as a framework for the BGA package. The substrate 105 comprises any material useful as an electrical insulator while providing sufficient rigidity to support a conductive pattern, wires 102, vias 103, and a die 103. The electrically insulating substrate material may comprise any material such as an organic polymer resin reinforced with glass fibers, bismaleimide-triazine (BT), polyimide resins, or epoxy resins such as FR-4 and FR-5. These materials may be formed at a desired thickness and otherwise formed with features necessary for a particular BGA package design as would be known to one skilled in the arts. In an embodiment, the substrate 105 may have a thickness of between 0.2 mm and 2 mm. In an embodiment, the substrate 105 may be produced in a larger sheet or pattern and singulated in a subsequent process to produce individual BGA packages.

A conductive pattern may be created on the substrate 105. As used herein, the term conductive pattern refers to a conductive metal disposed on a substrate that allows an electrical current or signal to be transmitted from one location to another location on the substrate. In an embodiment, a conductive pattern is created on the substrate by first depositing a conductive metal layer over the entire surface of the substrate, using for example electroless or electrolytic plating, and then subsequently etching the unwanted metal from the substrate. Alternatively, the conductive pattern may be created by screening the conductive metal through a mask placed on the substrate. Examples of suitable conductive metals include: copper, aluminum, titanium, tungsten, tantalum, platinum, molybdenum, cobalt, nickel, gold, iridium, or any combination thereof. The conductive pattern may also consist of a layered metal structure such that the conductive pattern may have one type of metal attached to the substrate and another type of metal that may be used for connecting to bonding pads or vias. For example, copper could be plated with gold to improve adhesion for the wire bond or solder ball. In an embodiment, a conductive pattern may be created on the substrate 105 in a single process for an entire substrate sheet, which may include a plurality of IC devices or die 100. The sheet may subsequently be singulated to form individual BGA packages.

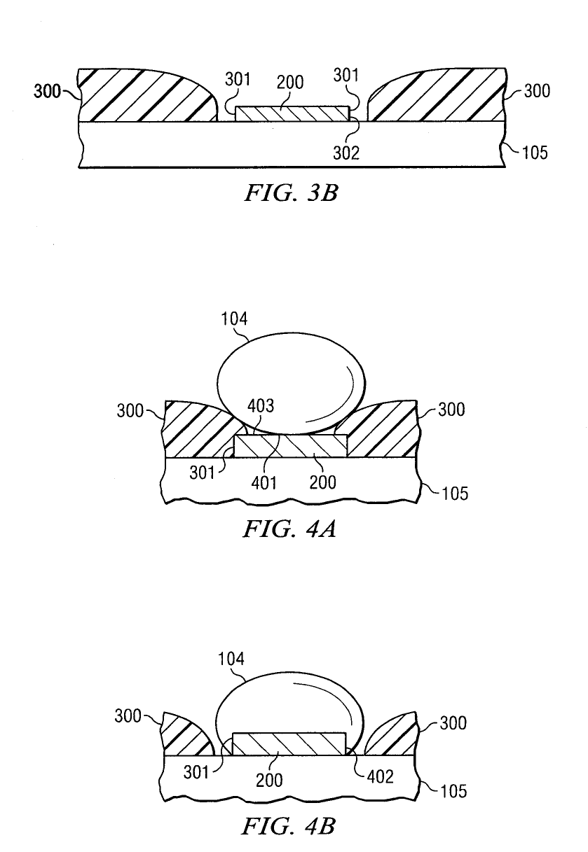

Referring to FIG. 2, a solder ball pad 204 may be disposed on the substrate 105 and may comprise a bonding pad 200 and one or more anchor pads 201. The term bonding pad 200 as used herein refers to the central area of a solder ball pad that is not substantially covered by the solder mask, is connected to a trace, and is attached to: (1) at least one anchor pad; (2) the substrate; and (3) solder. In an embodiment shown in FIGS. 2, 3A, and 3B, the bonding pad 200 may be formed on the side of the substrate 105 opposite the die 100. The bonding pad 200 may be disposed independently, at a separate time, or as part of a separate process from the conductive pattern and then electrically connected to the conductive pattern. In an alternative embodiment, the bonding pad 204 may comprise a portion of the conductive pattern and may be disposed on the substrate 105 at the same time as the conductive pattern.

Typically, a bonding pad edge 301 may be exposed within the solder mask opening 203 or may be between the solder mask 300 and substrate 105. The bonding pad edge 301 refers to the outer perimeter of the bonding pad 200 that may extend substantially perpendicular to the substrate 105 surface. The bonding pad edge 301 may be available for bonding to a solder ball 303.

Referring to FIGS. 4A and 4B, the mechanical strength of a bond between a bonding pad 200 and a solder ball 104 may be determined in part by the strength of the connection between the solder ball 104 and the bonding pad surface 403 combined with the strength of the connection between the solder ball 104 and the bonding pad edge 301. As shown in FIGS. 4A and 4B, the bond between a solder ball 104 and a bonding pad 200 may have a stress location at the edge of the bond on the surface of the bonding pad 401. The stress location may move from the surface of the bonding pad 401 to the bonding pad edge 402 along the portions of the bonding pad edge 301 that are exposed in the solder mask opening 203. Without intending to be limited by theory, the solder ball bond may be stronger when the stress is located along the bonding pad edge 402 rather than the bonding pad surface 401. As a result, any increase in the length of the bonding pad edge 301 available for bonding may increase the solder ball mechanical bond strength.

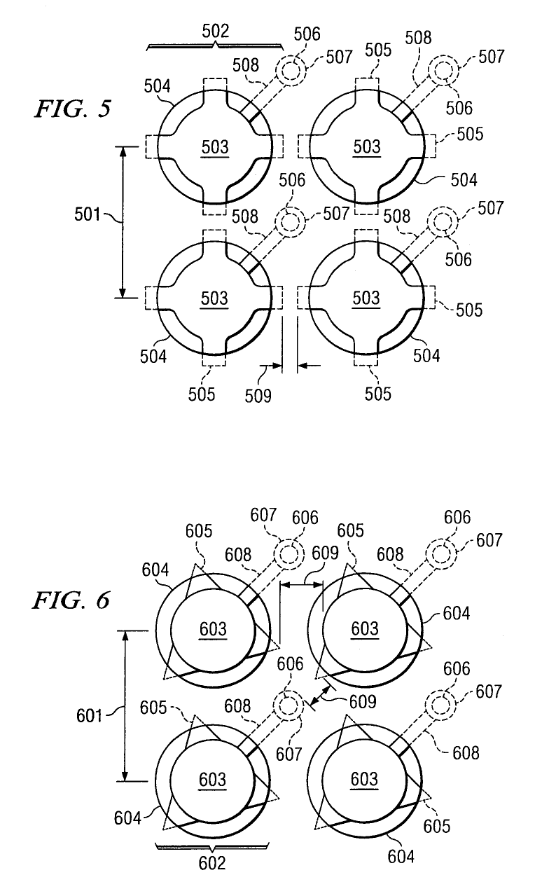

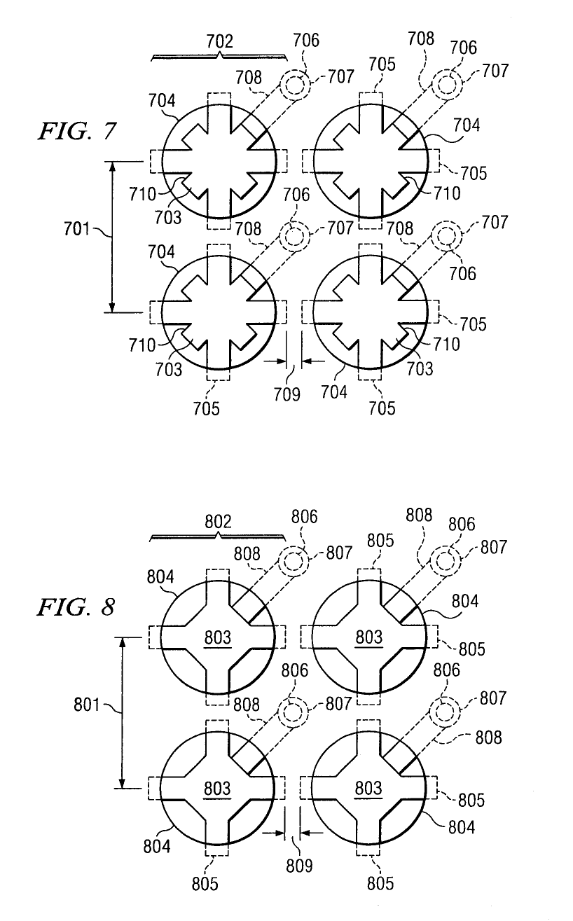

In an embodiment shown in FIG. 5, the bonding pad 503 portion of the solder ball pad may be circular in shape with its edges substantially exposed in the solder mask opening 504. Without intending to be limited by theory, a circular shape may create as large an area as possible within the solder mask opening 203 for bonding of the solder ball 303 to the bonding pad 200 surface. In an alternative embodiment shown in FIG. 7, the bonding pad 703 may be non-circular such that the bonding pad edge 710 length is increased for an improvement in the mechanical bonding strength between the bonding pad 703 and the solder ball. In an embodiment, a bonding pad 200 may have a circular diameter or non-circular width of between 100 μm and 300 μm. Alternatively, the bonding pad circular diameter or non-circular width may range from 25% to 75% of a solder ball pad array spacing, or pitch.

As shown in FIGS. 2 and 3, a solder ball pad 204 may comprise one or more anchor pads 201. The term anchor pad 201 as used herein refers to the portion of the solder ball pad that is connected to the bonding pad and the substrate and is at least partially covered by the solder mask. In an embodiment, the anchor pad 201 may be formed independently from the conductive pattern and connected to a part or extension of the bonding pad 200. In an alternative embodiment, the anchor pad 201 may comprise a portion of the conductive pattern and may therefore be connected to a part or extension of the bonding pad 200. The anchor pad 201 may comprise a conductive metal, including but not limited to the same conductive metal out of which the bonding pad 200 is formed. In an alternative embodiment, the anchor pad may comprise a non-conductive material capable of bonding to a bonding pad 200.

In general, the anchor pad 201 is intended to improve the mechanical connection of the bonding pad 200 to the substrate 105 while leaving the bonding pad edge 301 substantially exposed in the solder mask opening 300 for bonding to a solder ball 104. In certain circumstances, a BGA package may fail due to a separation of the bonding pad 200 from the substrate 105. In a typical BGA package where the solder mask 300 does not substantially cover the bonding pad 200 or bonding pad edges 301, only the interfacial connection between the bonding pad 200 and the substrate 105 holds the bonding pad 200 to the substrate 105. During impact or stress, the interfacial connection may be insufficient and may cause the bonding pad 200 to separate from the substrate 105, resulting in failure. By extending anchor pads 201 out from the bonding pad 200 between the substrate 105 and solder mask 300, the bonding pad 200 may obtain additional bonding strength from the mechanical connection to the solder mask 300 and substrate 105. Without intending to be limited by theory, the additional bond may result in the bonding pad 200 becoming less likely to fail due to separation from the substrate 105. The anchor pad 201 may be any length sufficient to extend between the solder mask 300 and the substrate 105 and any configuration so long as a portion of the anchor pad 201 extends under and is coupled to the solder mask 300 to support the bonding pad 200. In an embodiment, a typical anchor pad 201 length may be between 25 μm and 125 μm or between 50 μm and 100 μm. Alternatively, the anchor pad length may range from 25% to 50% of the bond pad circular diameter or non-circular width.

In an embodiment shown in FIGS. 2, 5, 6, 7, 8, and 9, an anchor pad 201 may have one of several shapes or configurations. An anchor pad 201 may have any shape or configuration that allows it to extend from the bonding pad 200 outward between the solder mask 300 and substrate 105 to support the bonding pad 200. The shape may depend on spacing and layout requirements of the BGA package. In an embodiment shown in FIG. 5, the anchor pad 505 may have a rectangular shape. In this embodiment, the anchor pad 505 may have a curved or tapered connection to the bonding pad 503, and the corners of the anchor pad 505 furthest from the bonding pad 503 may be rounded or tapered. The stress at a round corner is less that the stress at a sharp corner. In an alternative embodiment shown in FIG. 6, the anchor pad 605 may display a triangular shape. In this embodiment, the point of the triangle extends out from the bonding pad 603 between the solder mask 300 and the substrate 105. In this embodiment, the corners of the triangle may be slightly rounded and the connection between the anchor pad 605 and the bonding pad 603 may be curved. In an alternative embodiment, the anchor pad may have a square or circular shape. In an embodiment with more than one anchor pad, the anchor pads may all have the same shape or may comprise a combination of shapes.

A solder mask 300 may be applied to either side of the substrate 105 after the deposition of a conductive pattern on the surface. In a BGA package, the solder mask 300 comprises an electrically insulating, low surface tension material, which prevents bridging of the solder material and shorting between solder balls in a completed BGA package. The solder mask may have openings 203, which may help to position the solder ball 104 during a solder reflow process. In an embodiment, the solder mask 300 may comprise a photoimageable dielectric material, such as a negative or positive tone resist. In an embodiment, the solder mask 300 may be deposited through a blanket deposition on the substrate 105 surface, substantially covering the surface and the conductive pattern. The deposition may be accomplished using a suitable process such as spraying the mask material with a nozzle or moving the substrate 105 through a curtain of mask material.

Following deposition, the mask material may be partially hardened using a suitable curing process. An example of a curing process may include baking. The solder mask 300 may then be exposed to a pattern of radiation, for example, through the use of a mask. Following exposure of the material, a development step may be performed. Development may be performed using a suitable development process including exposure to a developing agent such as sodium monohydrate or potassium carbonate monohydrate. Following development, the solder mask 300 may be rinsed, dried, and cured.

The solder mask 300 deposition process results in an array of solder mask openings 203 leaving the bonding pads 200 substantially uncovered. More specifically, the solder mask openings 203 generally do not overlap the bonding pads 200. In order to achieve this goal, the solder mask 300 and the solder mask openings 203 must be aligned with the underlying conductive pattern. However, a small portion of the solder mask 300 may overlap the bonding pads 200 due to the differences in the manufacturing tolerances of the solder mask 300 and the bonding pads 200. The solder mask 300 registration tolerance refers to the distance about which the solder mask alignment may vary and still achieve the purpose of allowing for a solder mask opening 203 around the bonding pad 200. In some embodiments, a non-ideal alignment that is within the solder mask registration tolerance may result in only substantial, as opposed to complete, coverage of an area intended to be covered by the solder mask 300. Alternatively, non-ideal alignment within the solder mask registration tolerance may result in partial coverage of an area intended to remain uncovered. Thus, the bonding pad 200 remains substantially uncovered as long as the solder mask 300 remains within the solder mask 300 registration tolerance. Substantial solder mask 300 coverage in addition to complete solder mask 300 coverage is intended to be encompassed within the scope of this disclosure.

In an embodiment, the anchor pads 201 are substantially covered after the solder mask 300 has been applied, and the bonding pad 200 is substantially uncovered. In an embodiment, the solder mask 300 application process may result in a solder mask opening 203 that is round. However, a solder mask opening 203 of any shape capable of enclosing the anchor pad 201 between the solder mask 300 and the substrate 105 while leaving the bonding pad 200 substantially uncovered is intended to be within the scope of this disclosure. In an embodiment, a typical solder mask 300 registration tolerance may comprise a variance in placement of less than 60 μm or less than 50 μm.

The die 100 may be attached to the substrate 105 with a die attach material. The die attach material may be either an insulating or conductive material. If the vias 103 under the die 100 are used as a ground connection, then the die attach material may need to be electrically conductive. Thermally conductive material may also be useful if the substrate is used as a heat sink for the die 100.

The die 100 may be electrically connected to the conductive pattern. In an embodiment, the die 100 may be electrically coupled to the first substrate surface using a bond wire 102. In this embodiment, a bond wire 102 may be attached to the die 100 and then attached to a bonding pad 106 on the substrate surface. The wires may be arranged in a fashion so that they do not contact one another. Alternatively, the bond wires 102 may be insulated to prevent shorts in the event of a wire to wire contact. In an alternative embodiment, the die 100 may be electrically connected to the conductive pattern using an alternative connection procedure, for example a flip chip process or a TAB bonding process. There may be a one-to-one correspondence between a bonding pad 106 and the bond sites on the die 100. However, in certain embodiments one of the bond sites on the die 100 may be connected to more than one bonding pad 106 or more than one the bond site on the die 100 may be connected to a single bonding pad 106. The arrangement of contacts depends on the IC and the BGA package requirements and may be known to one skilled in the arts.

In an embodiment, a via 103 electrically connects a bonding pad 106 on the die 100 side of the substrate 105 to a solder ball pad 204, comprising a bonding pad 200 and one or more anchor pads 201, on the opposite side of the substrate 105. As used herein, the term via refers to an aperture extending through the substrate and includes an electrically conductive metal that extends through the substrate. The via 103 may be connected to a capture pad 206 at the surface of the substrate 105. As used herein, the term capture pad refers to a portion of electrically conductive material that connects the trace to the via. The via 103 may comprise a blind via, filled via, punched via, laser via, etched via, or built up via. In an embodiment, a BGA package may comprise a combination of via types. In an embodiment, a typical via capture pad 206 diameter may range from 100 μm to 300 μm. In an embodiment, the via capture pad 206 may be the solder ball bonding pad 200 or may be electrically connected to the bonding pad 200 by a trace 205. As used herein, the trace refers to a conductive pattern deposited on the substrate that has a first end and a second end, the first end being connected to a bonding pad, and the second end being connected to a bonding pad or a via. A trace 205 may comprise the same conductive metal or metals of the conductive pattern.

In an embodiment, a mold compound 101 may optionally be placed on the die 100 side of the substrate 105 subsequent to wire bonding. The mold compound 101 may comprise an epoxy that is formed and cured using a molding process into a desired shape. As an example of an alternative, the mold compound 101 may include without limitation polyimide resin, maleimide resin, silicone resin, phenol resin, polyurethane resin, acryl resin, or any combination thereof. The mold compound 101 protects the wires 102 and die 100, ensuring that they are mechanically stable during use.

A solder ball 104 may be attached to the bonding pad 200 in a BGA package. In an embodiment, the solder ball 104 may comprise a conductive metal or combination of metals. In an embodiment, the solder ball 104 may be mechanically and electrically connected to the bonding pad 200 using a reflow process. In this process, the solder ball 104 is temporarily connected to the bonding pad 200 through the application of a layer of flux applied to the bonding pad 200. A solder mask opening 203 over the bonding pad 200 may facilitate alignment of the solder ball 104 over the bonding pad 200. The package containing the bonding pad 200 with the solder ball 104 temporarily attached is then treated in a reflow oven. The oven heats the solder ball 104 above the solder melting point so that the solder ball 104 flows, which creates an electrical and mechanical bond with the bonding pad 200. After the reflow process, the solder ball 104 is typically no longer round and may exhibit a height from the surface of the bonding pad 200 less than prior to the reflow process. In an embodiment, the solder height after the reflow process may be about ⅔ of the solder ball height prior to the reflow process. The solder ball 104 may be of any size or volume so long as the height of the solder ball 104 protrudes above the solder mask 300 surface after the reflow process. A typically solder ball 104 height after reflow above the solder mask 300 may range from 0.190 mm to 0.360 mm.

A BGA package may comprise a substrate 105, a conductive pattern disposed on the substrate, a plurality of solder ball pads 502, and a solder mask 300. In general, the BGA package components may be arranged according to the conductive pattern and via 103 spacing requirements. In an embodiment, the components may be arranged in a grid pattern on the substrate 105. In high density applications, there may be little space available for arranging the solder ball pads 502 and routing the traces 205 between the bonding pads 200 and the respective vias 103. As shown in FIG. 5, the spacing of the solder ball pads 502 may be described by the solder ball pad pitch 501. As used herein the term pitch refers to the center to center spacing distance between nearby solder ball pads 502. Without intending to be limited by theory, a reduction in the pitch 501 may result in a smaller BGA package. Factors affecting pitch reduction include the anchor pad 201 length, the solder mask 300 registration tolerance, the minimum spacing distance between solder ball pads 502 or between solder ball pads 502 and via capture pads 206, trace 205 routing, and via 103 size and location. In an embodiment, the disclosed design may be used in a BGA package with a solder ball pad pitch in the range of 300 μm to 600 μm. In an embodiment, a typical minimum spacing between nearby solder ball pads 502 may range from 25 μm to 100 μm.

In an embodiment shown in FIG. 5, a BGA package is arranged in a grid pattern to reduce the solder ball pad pitch 501. As used herein, a grid pattern is intended to refer to a rectangular arrangement of solder ball pads 502 or solder ball pad centers on a surface of the substrate 105. The solder ball pads 502 are shown with circular bonding pads 503 and circular solder mask openings 504. Each bonding pad 503 has four anchor pads 505 that are rectangular in shape. A via 506 with an associated capture pad 507 is located in the interstices or central opening formed by the four solder ball pads 502. A trace 508 connects the via 506 to a single bonding pad 503. The grid pattern may repeat as many times as necessary to produce a required number of solder ball pad 502 connections. This embodiment reduces the pitch 501 of the grid layout by locating the via 506 at the center of a grid of four solder ball pads 502. The pitch 501 is limited by the minimum spacing distance between nearby solder ball pads 502. Specifically, this embodiment aligns the anchor pads 505 of nearby solder ball pads 502 so that the anchor pads 505 of one solder ball pad 502 extend along a line towards an anchor pad 505 of an nearby solder ball pad 502. The minimum spacing distance 509 may be limited by the distance between the ends of the anchor pads 505 on nearby solder ball pads 502.

In an embodiment shown in FIG. 6, a BGA package is shown with off-axis anchor pads 605. As used herein, off-axis is intended to refer to an anchor pad 605 placement in which the anchor pad 605 does not substantial align with an axis connecting nearby solder ball pad centers. In this embodiment, the bonding pads 603 have a round shape. The package contains three anchor pads 605 attached to each bonding pad 603 that are triangular in shape. A trace 608 couples each bonding pad 603 and via capture pad 607. The minimum spacing distance 609 between the nearby solder ball pads 601 may be determined as the lesser of the distance between an anchor pad 605 and an nearby bonding pad 603 or as the distance between the via capture pad 607 and the nearest anchor pad 605 end. The off-axis configuration may allow a reduction in the solder ball pitch 601 and BGA package size relative to a grid pattern with an on-axis design.

In an embodiment shown in FIG. 7, a BGA package is shown with non-circular bonding pads 703. In this embodiment, the solder ball pads 702 are arranged in a grid pattern with a via 706 and an associated capture pad 707 in the interstices formed by the four bonding pads 703. The anchor pads 705 are rectangular in shape and extend along a line towards an anchor pad 705 connected to a nearby solder ball pad 702. The bonding pads 703 are non-circular and consist of rectangular extensions aligned at a forty-five degree angle to the anchor pad 705 axis. The solder mask 300 does not substantially cover the rectangular bonding pad 703 extensions. The non-circular design allows for an increased bonding pad edge 710 length along which the solder ball may bond during a reflow process.

In an embodiment shown in FIG. 8, a BGA package is shown with a non-circular bonding pad 803. The solder ball pads 802 are shown with square bonding pads 803 rotated forty-five degrees relative to the anchor pads 805 and circular solder mask openings 804. Each bonding pad 803 has four anchor pads 805 that are rectangular in shape. The solder ball pads 802 are arranged in a grid pattern with a via 806 and an associated capture pad 807 in the interstices formed by the four solder ball pads 802. A trace 808 connects the via 806 to a single bonding pad 803. The grid pattern may repeat as many times as necessary to produce a required number of solder ball pad 802 connections. This embodiment aligns the anchor pads 805 of nearby solder ball pads 802 so that the anchor pads 805 of one solder ball pad 802 extend along a line towards an anchor pad 805 of a nearby solder ball pad 802. The solder ball pad pitch 801 may be limited by the minimum spacing requirements 809 as measured between the ends of the anchor pads 805 on nearby solder ball pads 802.

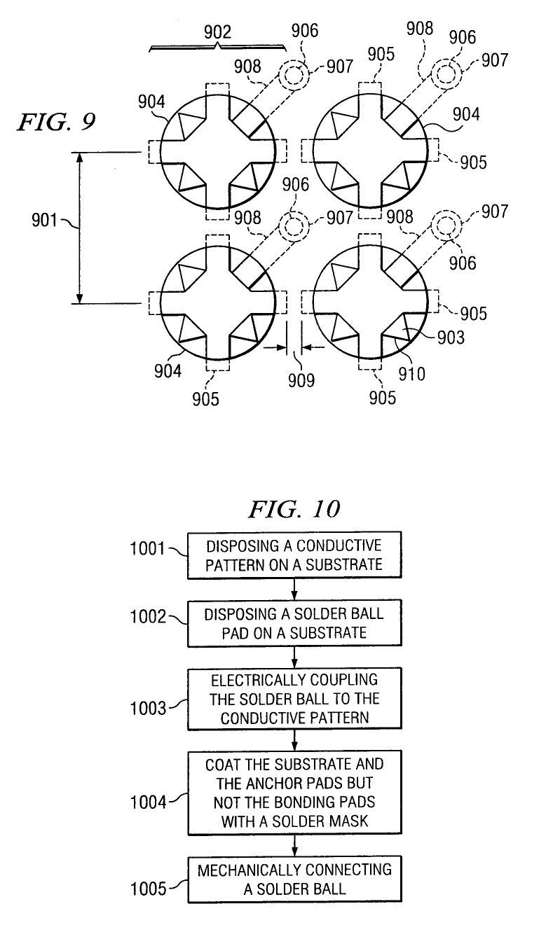

In an embodiment shown in FIG. 9, a BGA package is shown with non-circular bonding pads 903. In this embodiment, the solder ball pads 902 are arranged in a grid pattern with a via 906 and an associated capture pad 907 in the interstices formed by the four bonding pads 903. The anchor pads 905 are rectangular in shape and extend along a line towards an anchor pad 905 connected to a nearby solder ball pad 902. The bonding pads 903 are square and are rotated 45 degrees relative to the anchor pads 905. The bonding pad 903 also comprises triangular extensions aligned at a 45 degree angle to the anchor pad axis. The solder mask 300 does not substantially cover the triangular bonding pad 903 extensions. The non-circular design allows for an increased bonding pad edge 910 length along which the solder ball may bond during a reflow process.

The disclosed solder ball pad may exhibit improved performance in several BGA package quality control tests when compared to a substantially similar BGA package not using one or more of the disclosed designs. One such test is the mandrel bend test. In the mandrel bend test, a test vehicle is mounted to the BGA package, for example, using an adhesive to connect to the solder balls. After the package is bonded to the test vehicle, the package is bent across various mandrels having radii of 5.5 inches, 4.125 inches, 3 inches, 1.5 inches, and 0.75 inches. The smallest radius mandrel used represents the point at which the substrate 105 may begin to fail as opposed to the connection between the bonding pad 200 and the solder ball 104 or between the bonding pad 200 and the underlying substrate 105. Smaller radii mandrels may be used if the substrate 105 and BGA package is sufficiently flexible. The test measures whether delamination occurs for each mandrel. The largest mandrel is used first, followed by successively smaller mandrels until delamination occurs. The test is conducted at ambient temperatures. The results at each bend radius are recorded as pass or fail. A failure indicates an electrical, and therefore a mechanical, failure in the bonding pad 200 connection with the solder ball 104, the bonding pad 200 connection with the substrate 105 and trace 205, or the trace 205 connection with the via 103.

The disclosed solder ball pad design may also result in improvements in drop test results when compared to a substantially similar BGA package not using one or more of the disclosed configurations or techniques. The forces produced during a drop are reproduced in a gravity drop test. In this test, the BGA package is weighted similar to its end use application and dropped in a free fall from a height of 2 meters onto a concrete pad. The BGA package is oriented to drop flat faced onto the concrete pad with the BGA side of the substrate 105 facing downward. For the test, one hundred solder ball pad electrical connections are measured on the BGA package. The BGA package is repeatedly dropped until 50% of the electrical connections fail. Electrical connection failure indicates a mechanical bond failure either at the solder ball 104 bond with the bonding pad 200 or at the solder ball pad 204 interface with the substrate 105 or trace 205. The test is then continued until 100% of the solder ball pads 204 fail. The test results are reported as the number of drops to failure for 50% of the bonds and for failure of 100% of the bonds.

The disclosed solder ball pad design may also result in improvements in temperature cycle test results when compared to a substantially similar BGA package not using one or more of the disclosed configurations or techniques. A temperature cycle test exposes a BGA package to alternating upper and lower temperatures for a specified retention time at each temperature. Due thermal stresses, a typical BGA package will eventually show failures in response to the temperature cycling. Typical testing conditions for a BGA package may comprise an upper temperature of 125° C. and a lower temperature of −40° C. with a retention time of 30 minutes. Test results are reported as the first cycle during which a failure appears. A failure indicates an electrical, and therefore mechanical, failure between either the solder ball 104 and the bonding pad 200 or between the bonding pad 200 and the substrate 105 or trace 205.

In an embodiment shown in FIG. 10, a method for manufacturing a BGA package may include disposing a conductive pattern on a substrate 1001, disposing a solder ball pad on the substrate 1002, electrically coupling the solder ball to the conductive pattern 1003, coating the substrate with a solder mask 1004, and mechanically connecting a solder ball 1005. The steps of the disclosed method may be carried out in any order capable of produce the BGA package using any methods known to one skilled in the arts. In an embodiment, the method is carried out using the steps in the order listed above. In this embodiment, the solder ball pad comprises a bonding pad and an anchor pad, both of which are disposed on the substrate. Further, the solder mask may be coated on the substrate 1004 so that the solder mask substantially covers the conductive pattern and the anchor pads, but not the bonding pad. Finally, a solder ball may be mechanically and electrically connected to the package 1005 through a solder reflow procedure. The disclosed method may produce a BGA package with a design and properties consistent with those disclosed herein. The resulting BGA package may exhibit improved solder ball bonding characteristics when compared to a similar BGA package not using the disclosed design.

While several embodiments have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein, but may be modified within the scope of the appended claims along with their full scope of equivalents. For example, the various elements or components may be combined or integrated in another system or certain features may be omitted, or not implemented.

Also, techniques, systems, subsystems and methods described and illustrated in the various embodiments as discrete or separate may be combined or integrated with other systems, modules, techniques, or methods without departing from the scope of the present disclosure. Other items shown or discussed as directly coupled or communicating with each other may be coupled through some interface or device, such that the items may no longer be considered directly coupled to each other but may still be indirectly coupled and in communication, whether electrically, mechanically, or otherwise with one another. Other examples of changes, substitutions, and alterations are ascertainable by one skilled in the art and could be made without departing from the spirit and scope disclosed herein.

What is claimed is:

1. A solder ball pad comprising:
a substrate;
a bonding pad attached to the substrate, the bonding pad having a bonding pad surface and a bonding pad edge;
a solder mask attached to the substrate, the solder mask at least partially surrounding, but not substantially covering, the bonding pad; and
an anchor pad coupled to the bonding pad and extending at least partially between the substrate and the solder mask.

2. The solder ball pad of claim 1 further comprising a trace, the trace coupling the bonding pad to a via.

3. The solder ball pad of claim 1 wherein the bonding pad comprises an electrically conductive metal.

4. The solder ball pad of claim 1 wherein the bonding pad is in a shape intended to increase one of a length of the bonding pad edge and an area of the bonding pad surface available for bonding to a solder ball.

5. The solder ball pad of claim 1 further comprising a solder ball mechanically attached to the bonding pad.

6. The solder ball pad of claim 1 wherein the anchor pad comprises an electrically conductive metal.

7. The solder ball pad of claim 1 wherein the anchor pad is of a configuration selected from a group consisting of triangular, rectangular, square, and circular.

8. The solder ball pad of claim 1 wherein any corners of the bonding pad and any corners of the anchor pad are one of tapered and rounded.

9. A ball grid array package comprising:
a substrate;
a conductive pattern disposed on the substrate;
a solder ball pad disposed on the substrate and electrically coupled to the conductive pattern, the solder ball pad comprising a bonding pad and an anchor pad; and
a solder mask coated on the substrate, the solder mask substantially covering the conductive pattern and the anchor pads, and not substantially covering the bonding pad.

10. The ball grid array package of claim 9 further comprising a solder ball mechanically attached to the solder ball pad.

11. The ball grid array package of claim 9 further comprising a via extending through the substrate.

12. The ball grid array package of claim 9 further comprising a plurality of solder ball pads arranged in a grid pattern, the grid pattern comprising a rectangular alignment of the plurality of solder ball pads and a via located in the interstices between the plurality of solder ball pads.

13. The ball grid array package of claim 12 wherein the anchor pads are configured in an off-axis pattern, the off-axis pattern comprising an anchor pad placement in which the anchor pad does not substantial align with an axis connecting nearby solder ball pad centers.

14. The ball grid array package of claim 9 further comprising a bonding pad that is electrically coupled to a solder ball.

15. The ball grid array package of claim 9 wherein the solder ball is mechanically connected to the bonding pad edge.

16. A method of manufacturing a ball grid array package comprising:
disposing a conductive pattern on a substrate;
disposing a solder ball pad comprising a bonding pad and an anchor pad on the substrate, such that the solder ball pad is electrically coupled to the conductive pattern;
coating the substrate with a solder mask so that the solder mask covers at least a part of the conductive pattern and the anchor pads; and
connecting a solder ball to the bonding pad.

17. The method of claim 16 wherein the solder ball pads are disposed in a grid pattern with an off-axis configuration.

18. The method of claim 16 wherein the solder ball is mechanically connected to the edge of the bonding pad.

19. The method of claim 16 wherein the solder ball is mechanically connected to the surface of the bonding pad.

20. The method of claim 16 wherein the solder mask does not substantially cover the bonding pad.
